(19) United States
(12) Patent Application Publication
(10) Pub. No.: US 2025/0020272 A1
(43) Pub. Date: Jan. 16, 2025

(54) DEVICE FOR MECHANICALLY FASTENING A MODULE TO A WALL OF A PIECE OF EQUIPMENT HAVING A MOUNTING OPENING THAT RECEIVES THE MODULE

(71) Applicant: Eppendorf SE, Hamburg (DE)

(72) Inventors: Peteris Laganovskis, Hamburg (DE); Sören Mensch, Hamburg (DE); Tim Knutzen, Hamburg (DE); Andreas Ebbecke, Hamburg (DE)

(73) Assignee: Eppendorf SE, Hamburg (DE)

(21) Appl. No.: 18/770,061

(22) Filed: Jul. 11, 2024

(30) Foreign Application Priority Data
Jul. 13, 2023 (EP) 23 185 285.6

(51) Int. Cl. F16M 13/02; H05K 5/02

(52) U.S. Cl. CPC F16M 13/02; H05K 5/0217

(57) ABSTRACT

A device for mechanically fastening a module to a wall of a piece of equipment including a mounting opening, including a module carrier comprising a main body structured for insertion into the mounting opening and at least one first snap-in element. The module is connected to a front face of the main body. A support plate that is connected to one of: (i) the module carrier or (ii) module. A latching frame defining a frame opening and comprising at least one second snap-in element on an inner periphery. The first snap-in element and the second snap-in element are configured to snap together when the main body is inserted into the frame opening. A space is defined between the rear face of the support plate and the front face of the latching frame that is dimensioned for receiving an edge region of the wall surrounding the mounting opening.

### CROSS REFERENCE TO RELATED INVENTION

This application is based upon and claims priority to, under relevant sections of 35 U.S.C. § 119, European Patent Application No. 23 185 285.6, filed Jul. 13, 2023, the entire contents of which are hereby incorporated by reference.

### TECHNICAL FIELD

The following disclosure relates to a device for mechanically fastening a module to a wall of a piece of equipment having a mounting opening that receives the module.

### BACKGROUND

Laboratory equipment such as shakers, incubators, cyclers, thermomixers, centrifuges, automatic machines, and equipment for other fields of application often comprise a user interface (UI) module which is inserted in a mounting opening of a wall of the piece of equipment and fastened to the wall. The UI module is, for example, a membrane keyboard, a touchscreen, a combination of a PCBA (printed circuit board assembly) and input elements such as rotary knobs or membrane keys.

It is known to secure the UI module in the inserted position in the mounting opening by means of screws and/or adhesive bonding. It is further known to clip the module directly in a mounting opening of the piece of equipment.

The module and the wall with the mounting opening of the piece of equipment are constructed individually within the scope of respective equipment development process and customized. During every construction process, this customization results in an accordingly high workload for design, testing, and optimization.

The known screw connections of the module are releasable connections that are designed differently in many cases. Consequently, a large number of tools must be held available during production and servicing. Screw connections also have the disadvantage that installation space is lost in order to ensure that screwdriving tools can access the screw connections.

Adhesively bonding the module to the housing has the disadvantage that the final bonding result takes some time (up to several hours) to materialize after the act, which can be a hindrance during assembly and servicing. In addition, a reliable adhesive bond requires special manufacturing expertise. Removal is not possible without causing damage in the case of bonding. In the event of damage, entire equipment parts with the UI module may have to be exchanged in order to remedy an error.

A snap-in connection of the module directly to the piece of equipment requires precise adaptation of the module and mounting opening, including the tolerances and tools, which results in a high workload during development. Every injection molding tool for the equipment part with the mounting opening requires extensive adaptation to the tool or to the design for the UI module in order to integrate the UI module. This disadvantage is particularly noticeable for medium and small quantities.

CN 108800734 A describes a touch panel display which is fastened to a bracket by means of snap-in hooks. The bracket is inserted in an opening of a housing cover and the snap-in hooks are snapped together with the snap-in receptacles on the housing cover. The snap-in connection between the bracket and housing cover requires precise adaptation of the components to one another.

Proceeding from this, the object of the invention is to provide a device for mechanically fastening a module to a wall of a piece of equipment having a mounting opening that receives the module, wherein the workload for adapting the components to one another and for manufacturing the required tools is reduced.

### BRIEF SUMMARY OF THE INVENTION

An embodiment of a device for mechanically fastening a module to a wall of a piece of equipment having a mounting opening that receives the module includes a module carrier which has a planar main body for insertion into the mounting opening and at least one first snap-in element on the outer periphery of the main body. The module is arranged on the front face of the main body and is fastened to the module carrier. A support plate for support on a front side of the wall having the mounting opening, which support plate is connected to the module carrier or module and projects outwards in parallel with the main plane of the main body. A latching frame which has a frame opening for inserting a rear part of the main body and at least one second snap-in element on the inner periphery. At least one spring element is configured and arranged to resiliently support the latching frame on the rear side of the wall next to the mounting opening and/or to resiliently support the support plate on the front side of the wall. The first snap-in element and the second snap-in element are designed to snap together when the main body is inserted into the frame opening, wherein there is a spacing between the rear face of the support plate and the front face of the latching frame for receiving an edge region of the wall surrounding the mounting openings.

In an embodiment, the module carrier may be inserted by the planar main body thereof in the mounting opening of the piece of equipment. The module is arranged on the front face of the main body and is fastened to the module carrier. The module or module carrier includes a support plate by means of which the module carrier or module can be supported against the front side of the wall having the mounting opening of the piece of equipment. The latching frame includes a frame opening in which the rear part of the main body can be inserted. The device comprises at least one spring element which is designed and arranged to resiliently support the latching frame on the rear side of the wall next to the mounting opening and/or to resiliently support the support plate on the front side of the wall. The module carrier includes at least one first snap-in element on the outer periphery of the main body and the latching frame has at least one second snap-in element on the inner periphery. The first snap-in element and the second snap-in element are configured such that they can snap together when the main body is inserted in the frame opening. When the first snap-in element and the second snap-in element snap together, there is a spacing between the rear face of the support plate and the front face of the latching frame for receiving an edge region of the wall surrounding the mounting opening. This makes it possible to first insert the module carrier into the mounting opening and then, with the rear part of the latching frame, into the frame opening or, alternatively, to slide the latching frame with the frame opening onto the rear part of the main body. When the first snap-in element and the second snap-in element have been snapped together, the edge region of the wall surrounding the mounting opening is arranged between the rear face of the support plate and the front face of the latching frame. As a result, the support plate is supported against the front side of the wall and the latching frame is supported via the spring element against the rear side of the wall and/or the support plate is supported via the spring element against the front side of the wall and the latching frame is supported against the rear side of the wall.

In an embodiment, the device is secured to the piece of equipment by means of the module carrier engaging in the mounting opening and by means of the support plate and latching frame being clamped via the spring element on the front and rear side of the wall. Due to the differing elastic deformation of the spring element, tolerances between the module carrier, support plate, latching frame, and wall components can be compensated. It does not depend on precise adaptation of the module carrier and mounting opening, since the module carrier must only be inserted by the main body into the mounting opening and the support plate covers the gaps between the main body and the mounting opening. Rough tolerances can be set for the wall thickness of the wall and for the mounting opening in the housing. The tolerances for the wall thickness are compensated by the elastic deformation of the spring elements and the gaps that are left between the wall opening and the main body engaging therein due to the tolerances of the wall opening are covered by the support plate. The accuracies are set in the module carrier and latching frame of the device. The snap-in connection between the module carrier and the latching frame may be configured to be releasable, such that disassembly is possible. The snap-in connection may be designed such that the components can be mounted on and/or removed from the wall without a special tool.

The device may be configured such that the module carrier and latching frame or one of the two above-mentioned components can be used for various pieces of equipment. As a result, more identical parts can be used for various pieces of equipment. If one of the two components must be specifically adapted to different pieces of equipment, only minor changes may be necessary. This is the case, for example, if the module carrier must be specifically adapted to the provided module or to the piece of equipment. In addition, faster and simpler assembly and servicing can be achieved on account of the snap-in connection. Since the tolerances are compensated by means of the spring element being supported against the wall of the piece of equipment, the forces between the first snap-in element and the second snap-in element are not affected by the tolerance compensation or only negligibly affected thereby.

The construction workload for equipment to be newly developed can by reduced by the possible use of identical parts.

In an embodiment, when the support plate is connected to the module carrier, the clamping forces are diverted via the module carrier and kept away from the module. This can be advantageous, in particular, in the case of modules, for examples displays with a cover glass. When the support plate is connected to the module, the design can be improved as a result, because the module lies close to the housing wall and is not surrounded by the edge of a support plate of the module carrier. According to another embodiment, the support plate is integrally connected to the module carrier or to the module. As a result, manufacture and assembly can be simplified. In the case of an integral design with the module carrier, the support plate can be designed in the form of a frame which is connected at the inner periphery to a main body that projects backwards. The frame may delimit a cut-out that receives the module. In the case of an integral design with the module, the support plate can be designed as a laterally projecting edge region of a cover glass of a touch panel or another module.

According to another embodiment, the module carrier and the latching frame is rectangular or circular. In many cases, modules for use in equipment are rectangular or circular and the rectangular or circular configuration of the device allows for good adaptation and space-saving fastening of the device to the piece of equipment.

According to another embodiment, the module carrier includes a cut-out on the front face and the module is inserted in the cut-out. Protected and space-saving accommodation of the module on the module carrier is made possible by the cut-out. According to another embodiment, the cut-out is a window opening in the support plate and/or a recess in the main body of the module carrier.

According to another embodiment, the module is connected to the module carrier via an adhesive connection. As a result, stress-free fastening of the module to the module carrier can be achieved. Other ways of fastening the module to the module carrier are also possible, for example by clamping the module to the module carrier, by screwing or securing the module using securing rings or other securing means to the module carrier. Various types of fastening can also be combined.

According to another embodiment, the main body comprises a ribbed plate. As a result, a stable main body may be achieved with little use of material. A stable main body may prevent damage to a module from forces acting on the module carrier.

According to another embodiment, the module is a display, a monitor, a keyboard, a touchscreen, another UI module, or a transparent pane. The module may, in particular, be configured as a touch panel. The transparent pane may, in particular, be a viewing window, for example a pane on a centrifuge.

According to another embodiment, an electronic circuit board is arranged on the rear face of the main body. The electronic circuit board may be an electronic controller and/or an energy supply of an electronic module fastened to the module carrier.

According to another embodiment, screw domes project backwards from the rear face of the main body and the electronic circuit board is fastened to the screw domes by means of screws at screw holes. As a result, the electronic circuit board can be fastened in a secure as well as mounting-and servicing-friendly manner. According to another embodiment, positioning lugs project backwards from the rear face of the main body and the electronic circuit board is guided on the positioning lugs at positioning holes. As a result, exact orientation of the electronic circuit board on the module carrier is achieved.

According to another embodiment, the module carrier includes at least one backwardly projecting snap-in hook on the outer periphery and the latching frame has at least one snap-in receptacle for the snap-in hook on the inner periphery and/or the latching frame has at least one forwardly projecting snap-in hook on the inner periphery and the module carrier has at least one snap-in receptacle for the snap-in hook on the outer periphery. The snap-in hooks may be formed exclusively on the module carrier and the snap-in receptacles may be formed exclusively on the latching frame, or vice versa. It is also possible for both components to comprise snap-in hooks and also snap-in receptacles, wherein the arrangement of snap-in hooks and snap-in receptacles is adapted to one another, such that a snap-in hook of one component can be snapped together with the snap-in receptacle of the other component.

According to another embodiment, the latching frame has the snap-in hooks and the module carrier has the snap-in receptacles. In principle, the projecting snap-in hooks are more sensitive snap-in elements than the snap-in receptacles, since the snap-in hooks are laterally deflected prior to being snapped in. The arrangement of the latching hooks on the latching frame has the advantage that the more sensitive snap-in elements are arranged on the component that is particularly well suited as an identical part for use on various pieces of equipment and for cost-effective production with high quantities.

According to another embodiment, the snap-in hook has a one- or two-arm lever having a first lever arm having a hook for snapping into a snap-in receptacle and a second lever arm for releasing the snap-in connection with the snap-in receptacle. This is advantageous for servicing, because disassembly without the use of tools is simplified. The servicing personnel can open the piece of equipment in order to access the lever. According to another embodiment, the lever includes the second lever arm on the rear end. As a result, actuation of the lever may be facilitated when the piece of equipment is open.

According to another embodiment, the module carrier and/or the latching frame includes snap-in receptacles (latching receptacles) at multiple latching positions arranged one behind the other perpendicularly to the planar main body. As a result, latching of the module carrier to the latching frame is made possible at various latching positions in which there are different spacings between the rear face of the support plate and the front face of the latching frame. As a result, the device may be used with various pieces of equipment in which the wall having the mounting opening has different wall thicknesses. In addition, rough tolerances for the wall thickness of a piece of equipment can be covered by different latching steps.

According to another embodiment, the module carrier includes multiple first snap-in elements on the outer periphery and the latching frame has multiple second snap-in elements on the inner periphery. As a result, forces acting on the individual snap-in connections during the snap-in process can be kept low and uniform clamping of the device to the wall of the piece of equipment can be achieved. According to another embodiment, the module carrier only includes one single first snap-in element and the latching frame only has one single second snap-in element, wherein the first snap-in element extends completely around the outer periphery of the module carrier and the second snap-in element extends completely around the inner periphery of the latching frame. According to another embodiment, the module carrier includes multiple symmetrically arranged first snap-in elements on the outer periphery and the latching frame has multiple symmetrically arranged second snap-in elements on the inner periphery. This promotes uniform clamping of the device to the piece of equipment.

According to another embodiment, the spring element projects from the front face of the latching frame. By combining the spring element and latching frame into a single component, assembly and disassembly can be simplified. A gap between the device and the wall caused by tolerance compensation can be prevented by arranging the spring element on the rear side of the wall.

According to another embodiment, the latching frame includes, on the front face, at least one spring element that is configured as a flexible spring and that is inclined at an acute angle to the frame plane. The configuration of the spring element as an inclined flexible spring is particularly advantageous from a manufacturing point of view when manufactured by injection molding from plastics material.

According to another embodiment, the latching frame includes multiple symmetrically arranged spring elements. This is advantageous for uniform abutment and for compensating for different manufacturing tolerances on the periphery of the mounting opening. The invention also includes embodiments in which the latching frame only has one single spring element which may be formed, for example, by a circumferential, forwardly projecting and, if applicable, outwardly inclined resilient lip on the front face of the latching frame.

According to another embodiment, the support plate comprises the spring element. The spring element is formed, for example, by a circumferential, if applicable outwardly inclined, and backwardly projecting resilient lip on the outer periphery of the support plate or by a support plate designed as a whole as a disc spring consisting of resilient material.

According to another embodiment, the spring element is formed by a ring comprising an elastomer which is positioned between the latching frame and the rear side of the wall or between the support plate and the front side of the wall. The ring may, for example, be guided on the periphery of the main body and positioned on the rear side of the wall or on the front side of the wall. The ring may be designed as a rectangular ring or as a circular ring. In principle, an O-ring can be used for this purpose.

According to another embodiment, the snap-in hook is integrally formed with the module carrier or with the latching frame and/or the snap-in receptacle is integrally formed with the latching frame or module carrier and/or the spring element is integrally formed with the latching frame or support plate. Manufacture and assembly are simplified by the integral configuration of the above-mentioned structures with the above-mentioned components. Manufacture may take place, in particular, by means of injection molding from plastics material. Preferably, both the module carrier and the latching frame are injection-molded in one piece from plastics material.

According to another embodiment, the module carrier is produced from a plastics material or a metal and/or the latching frame is produced from a plastics material. According to another embodiment, the module carrier is produced from die-cast aluminum or milled metal.

According to another embodiment the module carrier is injection-molded from a plastics material and/or the latching frame is injection-molded from a plastics material (but could also be a two-component injection-molded part consisting of hard and soft components in order to perform a sealing function). According to another embodiment, the module carrier is configured in one piece and/or the latching frame is designed in one piece. According to another embodiment, the wall and/or a housing of the piece of equipment comprising the wall is produced from metal or plastics material. TSG, for example, may be used as the plastics material. According to a second embodiment, the housing is injection-molded from plastics material.

In the present application, the indications “front” and “rear” as well as terms comprising these directional indications, for example “front face” and “rear face”, relate to an arrangement of the device on an outer wall of a piece of equipment, wherein the module is arranged on the outer face of the piece of equipment, wherein the outer face thereof is visible to an observer looking at the piece of equipment from outside and the latching frame is arranged on the inside of the outer wall of the piece of equipment.

### BRIEF DESCRIPTION OF THE DRAWINGS

The device according to the invention is explained in more detail below based on the accompanying drawings of exemplary embodiments. In the drawings:

FIG. 1 illustrates an oblique rear view of an embodiment of a module carrier according to the disclosure.

FIG. 2 illustrates an oblique front view of an embodiment of a latching frame of the module carrier of FIG. 1.

FIG. 3 illustrates a rear perspective view of the embodiment of FIG. 1 at the start of the assembly process in a mounting opening of a piece of equipment.

FIG. 4 illustrates a rear perspective view of the embodiment of FIG. 1 after the module carrier has been inserted in the mounting opening and before the module carrier has been snapped together with the latching frame.

FIG. 5 illustrates a rear perspective view of the embodiment of FIG. 1 with the snapped-in module carrier and the latching frame clamped to the piece of equipment.

FIG. 6 illustrates a sectional view of another embodiment of a module carrier in a first latching step.

FIG. 7 illustrates the embodiment of FIG. 6 in a second latching step.

FIG. 8 illustrates the embodiment of FIG. 6 in a third latching step.

FIG. 9 illustrates a rear oblique view of another embodiment of a module carrier according to the disclosure.

FIG. 10 illustrates a front oblique view of an embodiment of a latching frame of the embodiment of FIG. 9.

FIG. 11 illustrates a perspective rear view of the embodiment of FIG. 9 at the start of the assembly process in a mounting opening of a piece of equipment.

FIG. 12 illustrates a perspective rear view of the embodiment of FIG. 9 after the module carrier has been inserted in the mounting opening and before the latching frame has been snapped together with the module carrier.

FIG. 13 illustrates a rear perspective view of the embodiment of FIG. 9 with the snapped-in module carrier and the latching frame clamped to the wall of the housing.

### DETAILED DESCRIPTION OF THE INVENTION

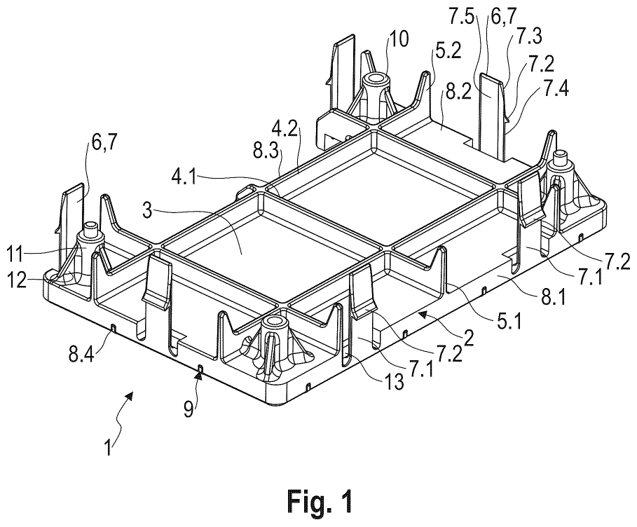

According to FIG. 1, an embodiment of a module carrier 1 comprises a rectangular, planar main body 2. The main body 2 includes a plate 3 and intersecting ribs 4.1, 4.2 that project from the rear face of the plate 3. The ribs 4.1, 4.2 partially comprise projections 5.1, 5.2 at the outer ends, which projections project backwards in the manner of hooks and which have outer edges that are oriented perpendicularly to the plate 3.

The main body 2 includes, on the outer periphery, first snap-in elements 6, which are formed as snap-in hooks 7 that project backwards perpendicularly from the base plate.

The snap-in hooks 7 each comprise one strip-shaped portion 7.1. A hook 7.2 in the form of a bar inclined at an acute angle to the strip-shaped portion 7.1 projects outwards from the strip-shaped portion 7.1 at a distance from the main body 2. The hook 7.2 is arranged at a distance from the rear end of the strip-shaped portion 7.1. The strip-shaped portion 7.1 has an inclined surface 7.3 on the outer face at the rear end. The snap-in hook 7 forms a single-arm lever with a shorter first lever arm 7.4 and a longer second lever arm 7.5, which can be pressed so as to be pivoted against the outer face of the second lever arm 7.5.

Two snap-in hooks 7 are arranged in each case on the two long sides of the main body 2 and one snap-in hook 7 is arranged in each case on the two short sides of the main body 2. Rectangular or bar-shaped side walls 8.1-8.4 of the main body 2, which delimit a cut-out in the form of a recess 9 on the front face of the main body 2, project forwards perpendicularly from the lateral edges of the plate 3 of the main body 2. The recess 9 is structured for insertion of a module.

Two diagonally arranged screw domes 10 and two diagonally arranged positioning lugs 11 project backwards at the four corners of the plate 3, which screw domes and positioning lugs are in each case supported on the rear face of the plate 3 by means of lateral ribbing 12.

For manufacturing-related reasons and in order to improve the resilience of the snap-in hooks, the planar main body 3 includes rectangular first perforations 13 on the inner faces of the snap-in hooks. In an embodiment, the module carrier 1 is manufactured in one piece by means of injection molding.

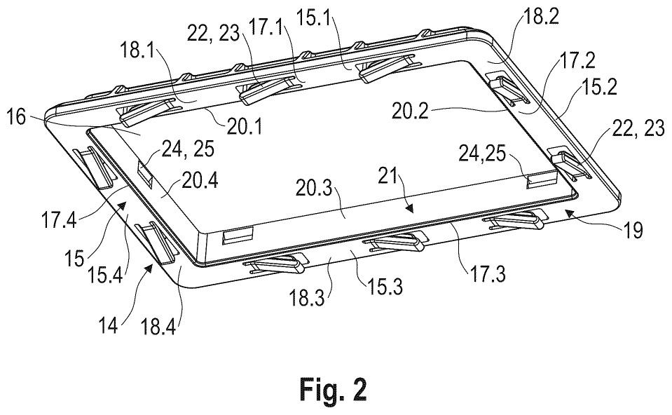

According to FIG. 2, an embodiment of a latching frame 14 includes a rectangular frame body 15 having four frame sides 15.1-15.4, which delimit a frame opening 16. The frame sides 15.1-15.4, in each case comprise L-shape profiles 17.1-17.4. First legs 18.1-18.4 of the L-shape profiles 17.1-17.4 coincide with the main plane (plane of greatest extent) of the latching frame 14 and together form an abutment portion 19 of the latching frame 14. Second legs 20.1-20.4 of the L-shape profile 17.1-17 extend forwards from the edge of the frame opening 16 vertically with respect to the main plane of the latching frame 14 and together form a connection portion 21 of the latching frame 14.

On the front face, the abutment portion 19 includes spring elements 22 in the form of flexible springs 23 that are inclined at an acute angle to the main plane. Three flexible springs 23 are arranged in each case on the two long frame sides 15.1, 15.3 of the latching frame 14 and two flexible springs 23 are arranged in each case on the two short frame sides 15.2, 15.4 of the latching frame 14. The flexible springs 23 are distributed substantially uniformly over the sides of the abutment portion 19.

On the inner periphery, the connection portion 21 comprises second snap-in elements 24 in the form of snap-in receptacles. The snap-in receptacles 25 are arranged on the front edge of the connection portion 21. Two snap-in receptacles 25 are arranged in each case on the two long frame sides 15.1, 15.3 and only one snap-in receptacle 25 is arranged in each case on the two short frame sides 15.2, 15.4. In an embodiment, the latching frame 14 is injection-molded in one piece from plastics material.

The shape and dimensions of the module carrier 1 and latching frame 14 are adapted to one another in such a way that the latching frame 14 can be pushed by the frame opening 16 thereof onto the module carrier 1 from behind, such that the snap-in hooks 7 engage in the frame opening 16 and connection portion 21 and snap together with the snap-in receptacles 25 by engaging by the hooks 7.2 in the snap-in receptacles 25. In this position, the front face of the abutment portion 19 of the latching frame 14 is at a distance from the front face of the main body 2, such that this spacing region can receive the edge region of a mounting opening of a wall of a piece of equipment.

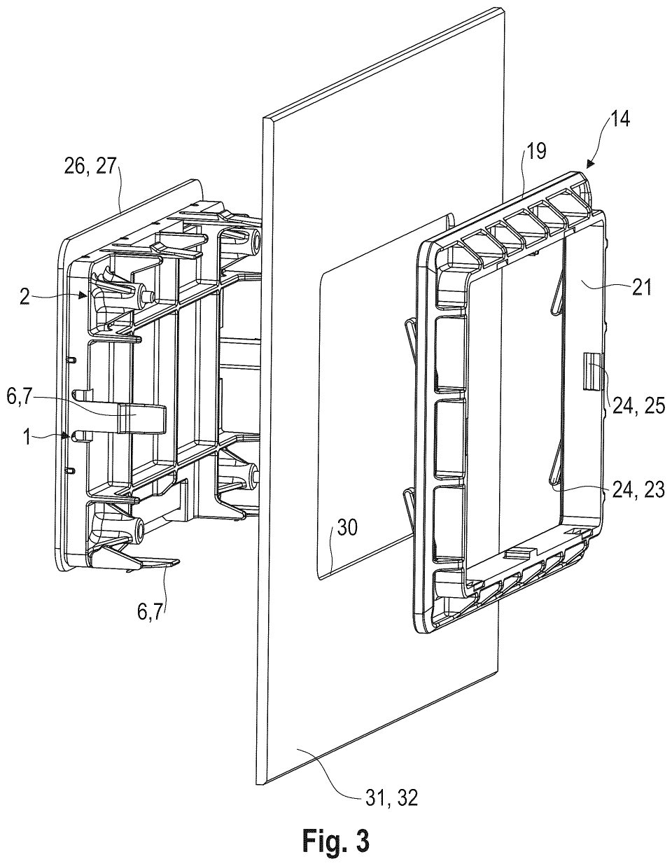

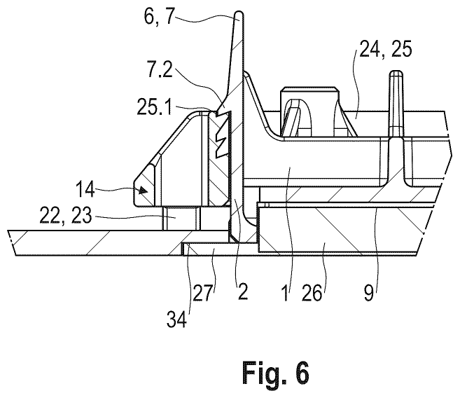

The recess 9 of the module carrier 1 serves to receive a touch panel or another module. According to FIG. 3, a module 26 is inserted in the recess 9, wherein the module 26 has a support plate 27, for example in the form of a display glass, which projects outwards in the sides of the main body 2 in parallel with the main plane (plane of greatest extent) of the main body 2. In the exemplary embodiment of FIG. 6, which comprises the same module carrier 1 as in FIG. 1 and a latching frame 14 that deviates from FIG. 2, the module 26 is shown in the recess 9. The module 26 is fastened to the module carrier 1 by means of an adhesive connection.

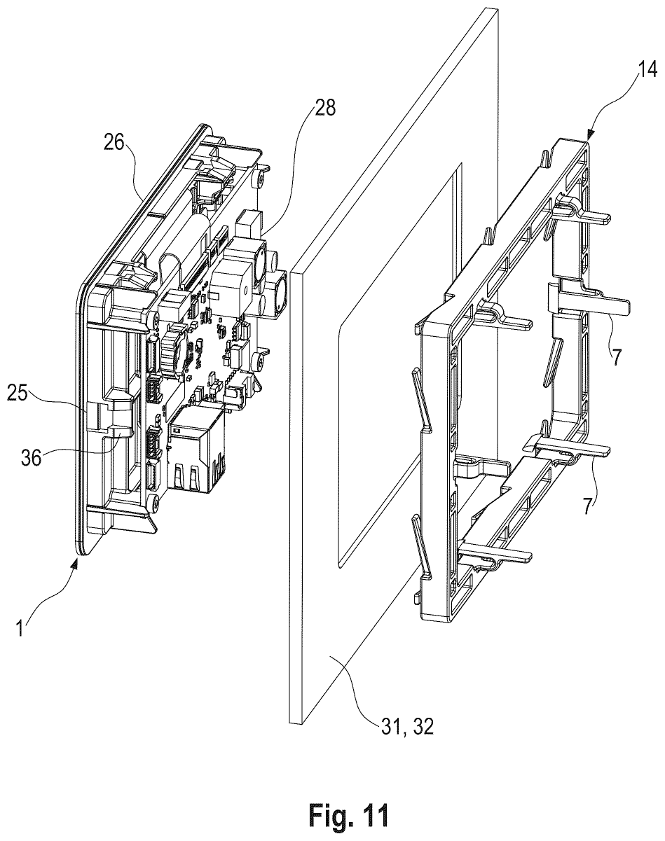

A rectangular electronic circuit board 28 includes holes at the edges can be mounted on the rear face of the module carrier 1. The positioning lugs 11 are introduced into two positioning holes arranged diagonally on the electronic circuit board 28 and screws 29 are inserted through the two diagonally arranged screw holes and screwed into the screw domes 10. In the present exemplary embodiment, this is omitted and shown for another exemplary embodiment in FIGS. 11 to 13.

According to FIG. 3, at the start of the assembly process, the module carrier 1 and latching frame 14 are oriented onto a rectangular mounting opening 30 in a wall 31 of a housing 32 of a piece of equipment. The wall 31 may be an outer wall of a housing 32. In principle, the wall 31 may also be an inner wall of a piece of equipment, for example a wall which separates two functional regions of the piece of equipment from one another. The dimensions of the mounting opening 30 slightly exceed the outer dimensions of the main body 2.

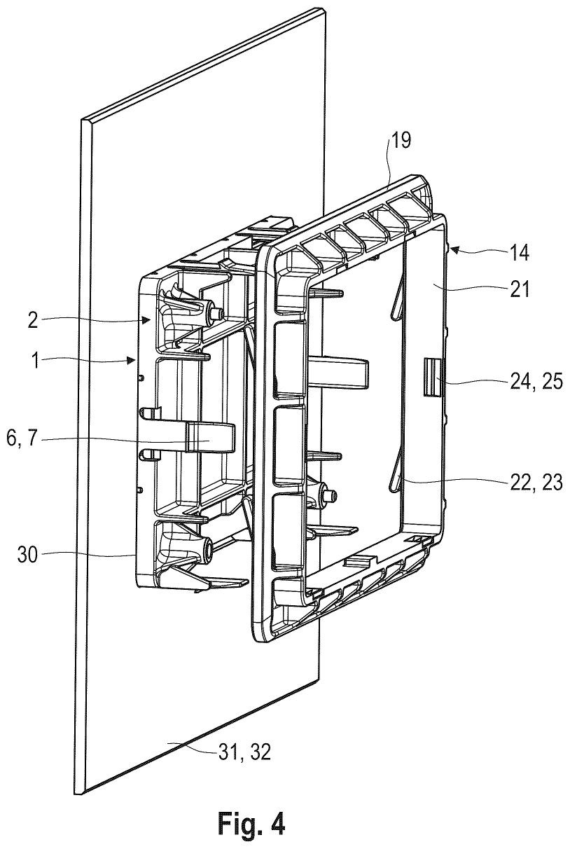

According to FIG. 4, in another assembly step, the module carrier 1 is inserted with the main body 2 in the mounting opening 30 until the support plate 27 is supported on the front side of the wall 31.

Finally, the latching frame 14 is pushed onto the module carrier 1 from behind until the spring elements 22 are supported on the rear side of the wall 31, are deflected somewhat, and the snap-in hooks 7 snap into the snap-in receptacles 25.

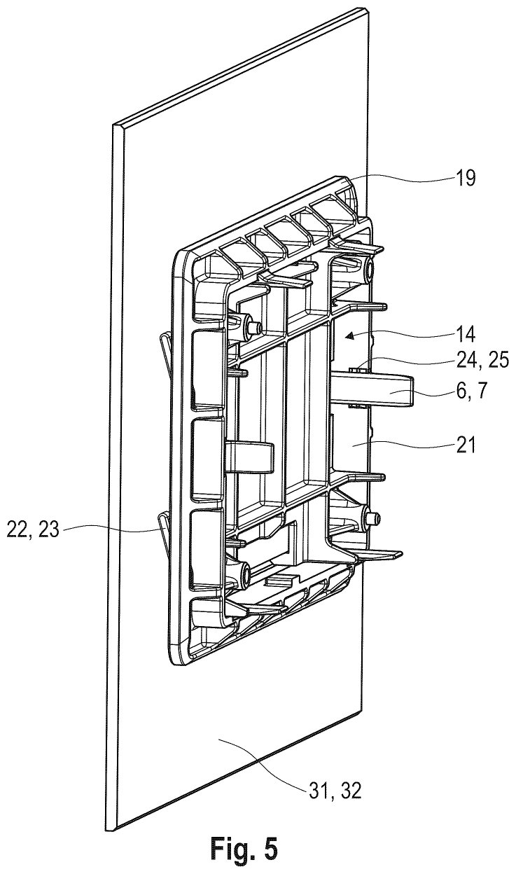

In FIG. 5, the device is shown in the installed position, in which the module carrier 1 and the latching frame 14 have been snapped together and the spring elements 22 are supported against the wall 31 in an elastically deformed manner. In the installed position, the device 33 comprised of the module carrier 1, module 26, and latching frame 14 is clamped against the wall 31 at the outer edge of the mounting opening 30. The manufacturing tolerances of the device 33 and wall 31 are compensated by the spring elements 22. This does not depend on precise adaptation of the mounting opening 30 and module carrier 1, since the support plate 27 covers gaps between the mounting opening 30 and module carrier 1 on the outside.

The device 33 may be assembled in an extremely simple manner without any tools. Disassembly is also easy and possible without tools. For this purpose, the opposing snap-in hooks 7 of the module carrier 1 at the rear ends can be compressed somewhat until the hooks 7.2 come free from the snap-in receptacles 25. Subsequently, the latching frame 14 can be pulled off of the module carrier 1 and the module carrier 1 can be removed from the mounting opening 30.

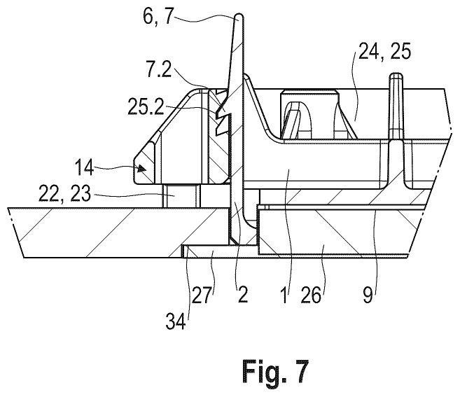

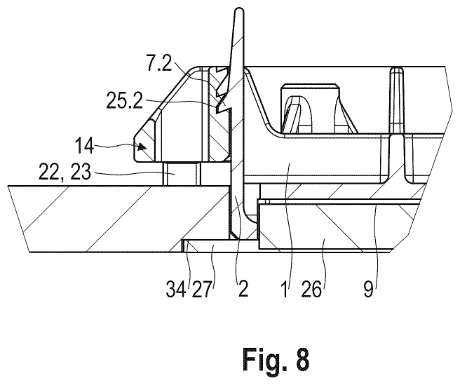

The exemplary embodiment from FIGS. 6 to 8 differs from the exemplary embodiment of FIGS. 1 to 5 in that the connection portion 21 of the latching frame 14 has snap-in receptacles 25.1, 25.2, 25.3 at multiple latching positions arranged one behind the other perpendicularly to the abutment portion 19. Consequently, the module carrier 1 and the latching frame 14 may be snapped or rather latched together in various latching positions. This is advantageous for roughly compensating for manufacturing tolerances and for using the device 33 with various pieces of equipment in which the mounting opening 30 is formed in walls 31 having different wall thicknesses.

The rear edges of each snap-in receptacle 25.1, 25.2, 25.3 are inclined backwards according to the inclination of the rear side of each hook 7.2 in order to facilitate displacement of the latching frame 14 into a subsequent latching position.

In addition, this exemplary embodiment includes, on the front side of the wall 31, an outer step 34, which extends around the mounting opening 30 and is dimensioned such that it receives the support plate 27. Consequently, the front face of the support plate 27 is flush with the front side of the wall 31 next to the outer step 34. The gap between the outer periphery of the support plate 27 and the outer boundary of the outer step can be kept small. In the view from outside, the module 26 is perfectly integrated in the wall.

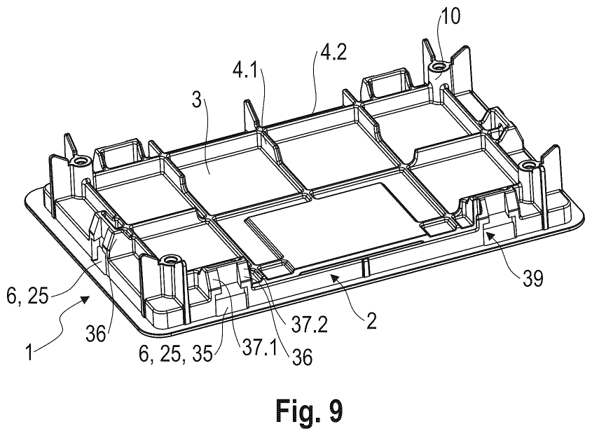

The exemplary embodiment of FIGS. 9 to 13 differs from the exemplary embodiment of FIGS. 1 to 5 in that the first snap-in elements 6 of the module carrier 1 are configured as snap-in receptacles 25 and not as snap-in hooks and in that the second snap-in elements 24 of the latching frame are designed as snap-in hooks 7 and not as snap-in receptacles. Another difference is that the support plate 27 is integrally formed with the module carrier 1 and not with the module 26.

The module carrier 1 has the snap-in receptacles 25 on the outer periphery of the bar-shaped side walls 8.1-8.4. The snap-in receptacles 25 are configured as rectangular second perforations 35 in the module carrier 1. Two snap-in receptacles 25 are arranged in each case on the two long sides of the main body 2 and one snap-in receptacle 25 is arranged in each case on the two short sides of the main body 2.

On the rear face, the main body 2 includes backwardly projecting lead-in chamfers 36 next to the snap-in receptacles 25. The lead-in chamfers 36 are formed on the outer faces of backwardly projecting parallel cams 37.1, 37.2, which are interconnected by means of a connection web.

The support plate 27 comprises a rectangular frame 38 having a window opening 39 on the front side. At the edge of the window opening 39, the support plate 39 is integrally connected to the front edge of the bar-shaped side walls 8.1-8.4 surrounding the recess 9 and project outwardly in parallel with the main plane of the main body 2. The window opening 39 and the recess 9 together form a cut-out 40 for inserting and wiring up a module 26.

The main body 2 may comprise through-openings in order to connect an electronic module on the front side of the main body to an electronic circuit board on the rear side of the main body or to electronics in the piece of equipment by means of cables fed through said through-openings. The module carrier 1 is injection-molded in one piece from plastics material.

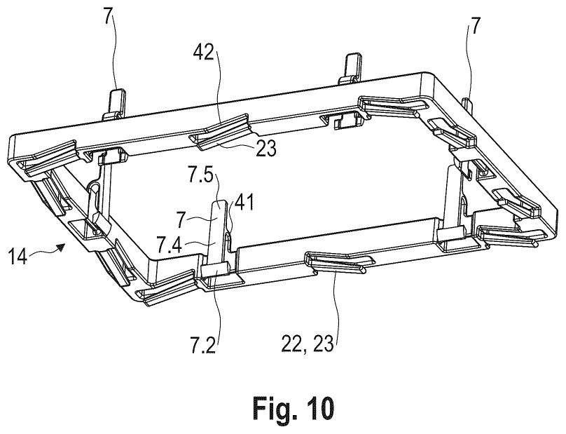

According to FIG. 10, the latching frame includes the snap-in hooks 7 on the inner periphery. Each snap-in hook 7 is connected to the front edge of the connection portion 21 via a connection tab 41. Each snap-in hook 7 comprises a strip-shaped portion 7.1, which extends perpendicularly to the abutment portion 19 and has an inwardly projecting hook 7.2 at the front end. The connection tab 41 is connected to the center of the strip-shaped portion 7.1. Thus the snap-in hook 7 is designed as a two-arm lever, having a first lever arm 7.4 from the hook 7.2 to the connection tab 41 and a second lever arm 7.5 from the connection tab 41 to the rear end of the strip-shaped portion 7.1, which can be pivoted by actuating the second lever arm 7.5.

The flexible springs 23 are arranged on the front face of the latching frame 14 above wedge-shaped notches 42 of the abutment portion 19, such that the flexible springs 23 are in each case joined to the abutment portion 19 via the deepest point of the notch 42. This arrangement is selected for increasing the fatigue strength and for manufacturing-related reasons. The latching frame 14 is injection-molded in one piece from plastics material.

A module (not visible in the figures) is glued in the cut-out 40 on the front face of the module carrier 1. According to FIGS. 11 to 13, an electronic circuit board 28 is secured on the rear face of the module carrier 1. According to FIG. 11, at the start of assembly, the module carrier 1 and the latching frame 14 are arranged on different sides of the mounting opening 30 and are aligned with it.

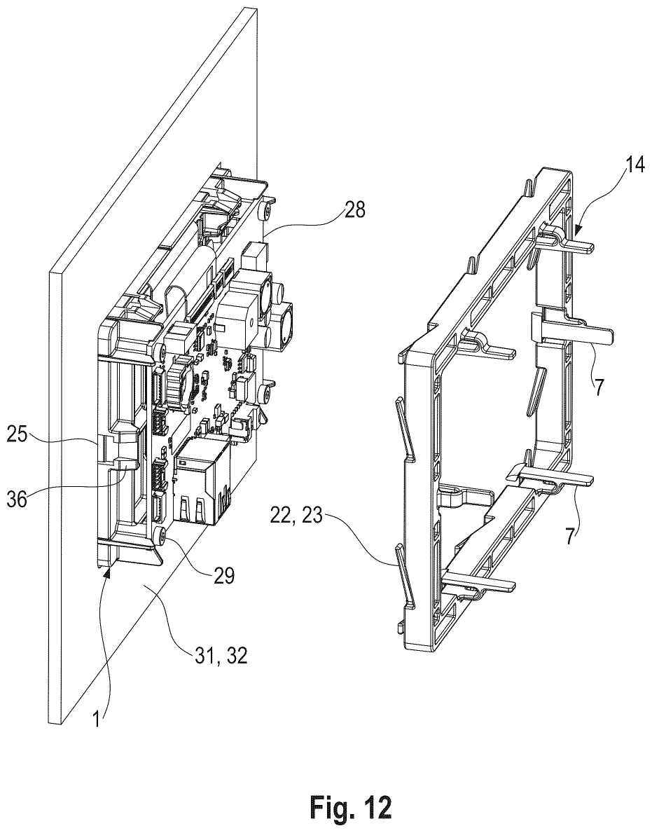

According to FIG. 12, the module carrier 1 is then pushed into the mounting opening 30 until the support plate 27 abuts the front side of the wall 31.

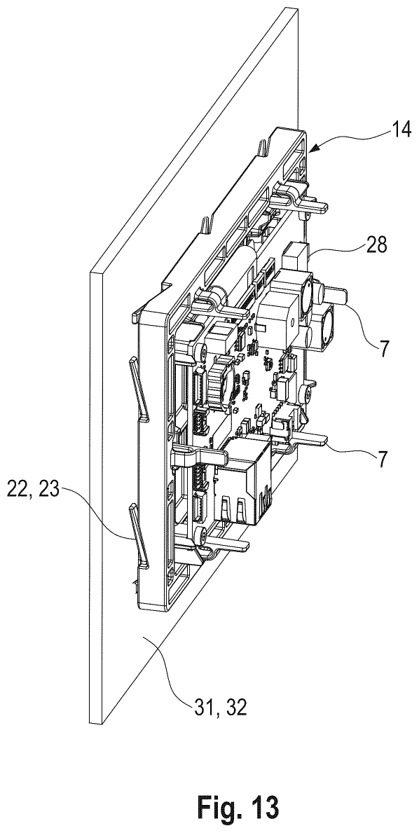

Finally, according to FIG. 13, the latching frame 14 is pushed onto the module carrier 1 from behind until the flexible springs 23 are supported on the rear side of the wall 31, are deflected somewhat, and the snap-in hooks 7 snap into the snap-in receptacles 25. The device is shown in the snapped-together installed position in FIG. 13.

In this embodiment, too, the spring elements 22 compensate for tolerances of the components 1, 14, 31 involved. The support plate 27 covers the edge region of the mounting opening 30, such that precise adaptation of the module carrier 1 to the mounting opening 30 is not required. Assembly can take place without the aid of tools. Disassembly is also simple, in that the rear ends of opposing snap-in hooks 7 are pivoted together to a certain extent. As soon as the hooks 7.2 come free from the snap-in receptacles 25, the latching frame 14 can be removed from the module carrier 1. Then, the module carrier 1 can be removed from the mounting opening 30.

Another advantage is that the snap-in hooks 7 are components of the latching frame 14, and therefore the latching frame 14 must be replaced in the event of failure. The latching frame 14 can preferably be used as an identical part for various pieces of equipment, and therefore this component can be replaced in a relatively cost-effective manner.

### LIST OF REFERENCE SIGNS

Module carrier
Main body
Plate
4.1, 4.2 Rib
5.1, 5.2 Projection
6 First snap-in element
7 Snap-in hook
7.1 Strip-shaped portion
7.2 Hook
7.3 Inclined surface
7.4 First lever arm
7.5 Second lever arm
8.1-8.4 Side wall
9 Recess
10 Screw dome
11 Positioning lug
12 Ribbing
13 First perforation
14 Latching frame
15 Frame body
15.1-15.4 Frame side
16 Frame opening
17.1-17.4 L-profile
18.1-18.4 First leg
19 Abutment portion
20.1-20.4 Second leg
21 Connection portion
22 Spring clement
23 Flexible spring
24 Second snap-in element
25 Snap-in receptacle
26 Module
27 Support plate
28 Electronic circuit board
29 Screw
30 Mounting opening
31 Wall
32 Housing
33 Device
34 Outer step
35 Second perforation
36 Lead-in chamfer
37.1, 37.2 Cam
38 Frame
39 Window opening
40 Cut-out
41 Connection tab
42 Notch

1. A device for mechanically fastening a module to a wall of a piece of equipment including a mounting opening dimensioned to receive the module, comprising:
a module carrier comprising,
a main body extending along a body plane and structured for insertion into the mounting opening, and
at least one first snap-in element on an outer periphery of the main body;
the module is positioned on a front face of the main body and fastened to the module carrier;
a support plate for support on a front side of the wall, wherein the support plate is connected to one of (i) the module carrier or (ii) module, and is configured to project outwards in parallel with the body plane;
a latching frame extending along a frame plane and defining a frame opening for inserting a rear face of the main body and comprising at least one second snap-in element on an inner periphery; and
at least one spring element configured to resiliently support at least one of: (i) the latching frame on a rear side of the wall and next to the mounting opening, and (ii) the support plate on the front side of the wall,
wherein the first snap-in element and the second snap-in element are configured to snap together when the main body is inserted into the frame opening,
wherein a spacing is defined between a rear face of the support plate and the front face of the latching frame that is dimensioned for receiving an edge region of the wall surrounding the mounting opening.

2. The device according to claim 1, wherein the support plate is integrally connected to one of: (i) the module carrier; or (ii) the module.

3. The device according to claim 1, wherein the module carrier defines a cut-out on the front face and wherein the module is inserted into the cut-out.

4. The device according to claim 1, wherein the module is connected to the module carrier via an adhesive connection.

5. The device according to claim 1, wherein the module is a display, a monitor, a keyboard, a touchscreen, another UI module, or a transparent pane.

6. The device according to claim 1, further comprising:
a plurality of screw domes project backwards from the rear face of the main body; and
an electronic circuit board fastened to the plurality of screw domes by means of screws.

7. The device according to claim 1, wherein:
the module carrier comprises at least one backwardly projecting snap-in hook on the outer periphery;
the latching frame comprises: (i) at least one snap-in receptacle for the snap-in hook on the inner periphery; and (ii) at least one forwardly projecting snap-in hook on the inner periphery; and
the module carrier comprises at least one snap-in receptacle for the snap-in hook on the outer periphery.

8. The device according to claim 7, wherein the snap-in hook comprises a one- or two-arm lever including a first lever arm and comprising a hook configured for snapping into a snap-in receptacle and a second lever arm configured to release the snap-in connection with the snap-in receptacle.

9. The device according to claim 1, wherein at least one of: (i) the module carrier; and (ii) the latching frame, comprise snap-in receptacles at multiple latching positions arranged one behind the other perpendicularly to the main body.

10. The device according to claim 1, wherein the module carrier comprises multiple first snap-in elements positioned on the outer periphery and wherein the latching frame comprises multiple second snap-in elements on the inner periphery.

11. The device according to claim 1, wherein the spring element is configured to project from the front face of the latching frame.

12. The device according to claim 1, wherein the latching frame comprises, on the front face, at least one spring element that is configured as a flexible spring and inclined at an acute angle to the frame plane.

13. The device according to claim 7, wherein the snap-in hook is integrally formed with one of: (i) the module carrier; or (ii) the latching frame.

14. The device according to claim 13, wherein the at least one snap-in receptacle is integrally formed with one of: (i) the latching frame; or (ii) the module carrier.

15. The device according to claim 14, wherein the spring element is integrally formed with one of: (i) the latching frame; or (ii) the support plate.

16. The device according to claim 1, wherein the module carrier is formed from a plastics material.

17. The device according to claim 16, wherein the latching frame is formed from a plastics material.

18. The device according to claim 1, wherein at least one of the module carrier or the latching frame is formed by an injection molding process.
